(19) United States
(12) Patent Application Publication
(10) Pub. No.: US 2006/0040432 A1
(43) Pub. Date: Feb. 23, 2006

(54) Thin film trnsistor, method for producing a thin film transistor and electronic device having such a transistor

(75) Inventors: Carl Glasse, Redhill (GB); Stanley D Brotherton, Forest Row (GB)

Correspondence Address: PHILIPS ELECTRONICS NORTH AMERICA CORPORATION;INTELLECTUAL PROPERTY & STANDARDS, 1109 MCKAY DRIVE, M/S-41SJ, SAN JOSE, CA, 95131, US

(73) Assignee: KONINKLIJKE PHILIPS ELECTRONICS N.V., EINDHOVEN (NL)

(21) Appl. No.: 10/540,410

(22) PCT Filed: Dec. 11, 2003
(86) PCT No.: PCT/IB03/05940

§ 371 Date: Jun. 24, 2005

(30) Foreign Application Priority Data
Dec. 24, 2002 (GB) 0230140.6

(51) Int. Cl. H01L 21/84

(52) U.S. Cl. 438/151

(57) ABSTRACT

A thin film transistor (100) is mounted on a substrate (102), which is covered by a semiconductor layer (120). The semiconductor layer (120) has a first doped region (121) and a second doped region (122) with an undoped region (123) in between. In addition, the semiconductor layer (120) has a first further doped region (125) and a second further doped region (126) forming the source and drain of the thin film transistor (100) and being more heavily doped than the first doped region (121) and the second doped region (122). A part of the semiconductor layer (120) is covered by an oxide layer (140), which carries a conductive gate (104) over the undoped region (130) and a first spacer (111) and second spacer (112) over the first doped region (121) and the second doped region (122) respectively. In addition, the oxide layer (140) carries a first insulating spacer (125) and a second insulating spacer (126) to provide adequate insulation between the gate structure and a first conducting contact (135) and a second conducting contact (136) respectively. Because the first spacer (111), the second spacer (112), the first insulating spacer (115) and the second insulating spacer (116) are mounted on the oxide layer (140), a thin film transistor (100) with favourable parasitic conductivity characteristics is obtained.

The present invention relates to a thin film transistor on a substrate comprising a layer structure comprising: a semiconductor layer having a first doped region and a second doped region in between a first further doped region and a second further doped region, and having an undoped region in between the first doped region and the second doped region, the first doped region and the second doped region having a lower conductivity than the first further doped region and a second further doped region; and an oxide layer partially covering a surface of the semiconductor layer.

The present invention also relates to a method for producing such a thin is film transistor.

The present invention further relates to an electronic device having a matrix array coupled to a first driver circuit arrangement and a second driver circuit arrangement, at least one of the matrix array, first driver circuit arrangement and a second driver circuit arrangement comprising a plurality of thin film transistors.

Thin film transistors (TFTs) are commonly used in active matrix array devices like liquid crystal display (LCD) devices and memory devices. However, the use of TFTs in such devices is not without problems. For instance, to ensure that the performance of the TFTs allows for high performance applications, the TFT has to be able to perform high switching speeds. Such demands can for instance be met by TFTs having polysilicon or crystalline silicon semiconductor layers with relatively short channel lengths. However, such devices have the drawback that a large field gradient is present between the highly doped drain area and the undoped area under the gate, which can lead to hot carrier injection effects between the drain and gate of the TFT, which can seriously damage the TFT.

This problem can be reduced by introducing a secondary, lightly doped region into the semiconductor layer inside the highly doped drain region of the TFT. This lightly doped region introduces a reduction in the field gradient between the highly doped region and the undoped region under the gate, and is also known as a field-relief region for that reason. Consequently, a more gradual voltage drop between the highly doped region and the undoped region under the gate is obtained, which for instance reduces the occurrence of damaging hot carrier injection effects. Typically, for reasons of simplicity, two lightly doped regions are implemented in between the more heavily doped regions. These lightly doped regions are easily implemented using a self-aligned process in which the conductive gate of the TFT is used as a mask. The lightly doped regions may be covered by conducting spacers covering the sides of the conductive gate to ensure better controllability of the hot carrier effects as well as to obtain an enhanced conducting contact, that is, a better conducting channel under the conductive gate between the source and drain. The arrangement of the conductive gate and adjacent spacer can be used as a mask to implement the drain and source regions.

However, this arrangement introduces another problem. TFTs with relatively short channels have a relatively good channel conductivity. However, as a consequence, the overall series resistance between the source electrode and the drain electrode becomes an issue. Therefore, rather than having a conductive contact with a confined part of the source or drain area, the source and drain surfaces may be largely covered by a conductive contact, thus reducing the distance between the source and drain electrodes and reducing the series resistance as a consequence. However, if these conductive contacts extend over a large area of the source and drain surfaces, the distances between the conductive contacts and the conducting gate can become small, especially when conducting spacers are used to cover the field relief regions. Consequently, a short circuit between the conducting gate and the conductive contacts can occur more easily, which renders the TFT inoperable.

U.S. Pat. No. 6,410,373 discloses a method for producing a polysilicon TFT, wherein a second set of insulating spacers are introduced in between the set of conducting spacers being formed by selective deposition on the one end and the salicide source and drain electrodes on the other end. The insulating spacers cover the sides of the conducting spacers and are formed by removing a portion of the oxide layer and forming an insulating spacer on a sidewall of a conducting spacer. The insulating spacer increases the lateral insulation between the conductive gate and a source or drain salicide electrode, thus reducing the risk of shorts between gate and source or drain.

In practice, the measures as disclosed in the U.S. Pat. No. 6,410,373 are not satisfactory. One of the problems is that parasitic currents can run between the conductive gate and the heavily doped source and drain areas via the contact area between the conducting spacer and the insulating spacer, which operates as a conductive parasitic path between the conducting gate and the source and drain regions. This is a serious problem, because these currents can be high enough to render the TFT inoperable.

It is a first object of the invention to provide a TFT that has a less conductive parasitic path between the conductive gate and the source/drain areas.

It is a second object of the invention to provide a method for producing a TFT that has a less conductive parasitic path between the conductive gate and the source/drain areas.

It is a third object of the invention to provide for an electronic device benefiting from the less conductive parasitic path between the conductive gate and the source/drain areas of the TFT.

The invention provides a thin film transistor on a substrate comprising a semiconductor layer having a first doped region and a second doped region in between a first further doped region and a second further doped region, and having an undoped region in between the first doped region and the second doped region, the first doped region and the second doped region having a lower conductivity than the first further doped region and a second further doped region and an oxide layer partially covering a surface of the semiconductor layer, the oxide layer carrying:

a conductive gate over the undoped region having a first side and a second side substantially perpendicular to the oxide layer; a first spacer and a second spacer adjacent to the first side and second side of the conductive gate respectively; a first insulating spacer adjacent to a side of the first spacer opposite the first side of the conductive gate; and a second insulating spacer adjacent to a side of the second spacer opposite the second side of the conductive gate; the TFT further comprising a first conductive contact with the first further doped region; and a second conductive contact with the second further doped region.

The location of the first insulating spacer and the second insulating spacer on the oxide layer removes the presence of a leakage path to the first further doped region and the second further doped region, that is, the source and drain areas in the semiconductor layer via the contact surfaces between the first spacer and the first insulating spacer and the second spacer and the second insulating spacer. Consequently, the parasitic path between the conductive gate and the first further doped region and the second further doped region is extended by the full length of the oxide layer underneath an adjacent insulating spacer to reach a doped region in the semiconductor layer. This substantially reduces the conductivity of the parasitic path between the conductive gate and the first and second further doped regions.

In an embodiment, the first spacer and second spacer comprise a conductive material.

Although the first spacer and the second spacer may be insulating spacers, as for instance is disclosed in U.S. Pat. No. 5,786,241, it is advantageous to use conductive spacers over the first and second doped regions, because a better control over the hot carrier effects in the TFT as well as a better conductivity in the channel under the conductive gate is obtained.

In another embodiment, the first conductive contact and the second conductive contact comprise a silicide layer.

The formation of a silicide layer, over the exposed areas of the first and second further doped regions in the semiconductor layer has the advantage that good conducting contacts with the source and drain regions are obtained at relatively low cost.

In yet another embodiment, the semiconductor layer comprises a polycrystalline silicon material.

Even though the present invention is advantageous to TFTs having semiconductor layers that suffer from substantial parasitic currents, such layers including microcrystalline silicon and crystalline silicon, the present invention is particularly advantageous for application in polysilicon TFTs, because at least at the moment these types of TFTs provide a good trade-off between cost and performance.

The invention also provides a method for producing a thin film transistor on a substrate comprising a semiconductor layer having an undoped region in between a first doped region and a second doped region and an oxide layer partially covering a surface of the semiconductor layer, the oxide layer carrying a conductive gate over the undoped region having a first side and a second side substantially perpendicular to the oxide layer, the first doped region and the second doped region having been formed in a self-alignment step using the conductive gate as a mask, the method comprising the steps of providing a first spacer and a second spacer on the oxide layer adjacent to the first side and second side of the conductive gate respectively; implanting a first further doped region and a second further doped region into the semiconductor layer using the conductive gate, the first spacer and the second spacer as a further mask, the first further doped region and the second further doped region being more conductive than the first doped region and the second doped region; providing a first insulating spacer on the oxide layer adjacent to the first spacer opposite the first side of the conductive gate and a second insulating spacer on the oxide layer adjacent to the second spacer opposite the second side of the conductive gate; removing an exposed area of the oxide layer covering the first further doped region and the second further doped region; and providing the first further doped region with a first conductive contact and the second further doped region with a second conductive contact.

This has the advantage that a TFT is formed with both the first and second spacer as well as the first and second insulating spacer being located on top of the oxide layer, which provides for a TFT structure with a good insulation between the conductive gate and the first and second further doped regions in the semiconductor layer. By reducing the conductivity of the parasitic path between the conductive gate and source/drain areas, the yield of the TFT production process is improved, because less TFT structures will prove to be inoperable because of the presence of too large parasitic currents between the conductive gate and the source and drain areas

In an embodiment, the step of providing a first spacer and a second spacer comprises depositing a conductive spacer material.

This has the advantage that a good conductive contact between the conductive gate and the lightly doped first and second doped regions is obtained.

In another embodiment, the step of providing the first further doped region with a first conductive contact and the second further doped region with a second conductive contact comprises reacting a conductive material with the semiconductor layer to form a silicide.

Apart from the fact that using a silicide to form a conductive contact with the source and drain regions of the TFT is advantageous because of the obtained lower series resistance between the source and drain electrodes, the method of the present invention has an additional advantage. Because the formation of the various structures on the oxide layer take place with the oxide layer covering the areas of the semiconductor layer holding the first and second further doped regions, these areas are not exposed to these processing steps. Consequently, these areas are not contaminated by these processing steps. In fact, the only steps that these areas are directly exposed to are the removal of the oxide layer and the deposition of the conductive material for the silicide formation. This is advantageous, because the quality of the formed suicide degrades with increased levels of contaminants in the areas of the semiconductor layer that are reacted with the deposited conductive material to form the silicide.

In yet another embodiment, the step of removing an exposed area of the oxide layer covering the first further doped region and the second further doped region is performed using the conductive gate, the first spacer, the second spacer, the first insulating spacer and the second insulating spacer as a mask.

This has the advantage that this step can be performed in a self-aligned manner, thus further reducing the mask count for the process.

The invention further provides an electronic device comprising an active matrix array coupled to a first driver circuit arrangement and a second driver circuit arrangement, the first driver circuit arrangement and the second driver circuit arrangement being coupled to a power supply; at least one of the active matrix array, first driver circuit arrangement and a second driver circuit arrangement comprising a plurality of thin film transistors as described herein.

Such an electronic device benefits from the use of TFTs according to the present invention because the performance of the active matrix array is improved by the reduction of the conductivity of the parasitic paths between the gate and source/drain areas of the TFTs. Also, the demands on the power supply are reduced, because less currents leak away, which improves the lifetime of the power supply. This is particularly advantageous for power supplies like batteries or battery packs in portable electronic devices like mobile phones, personal digital assistants and laptop computers.

The invention is described in more detail and by way of non-limiting examples with reference to the accompanying drawings, wherein:

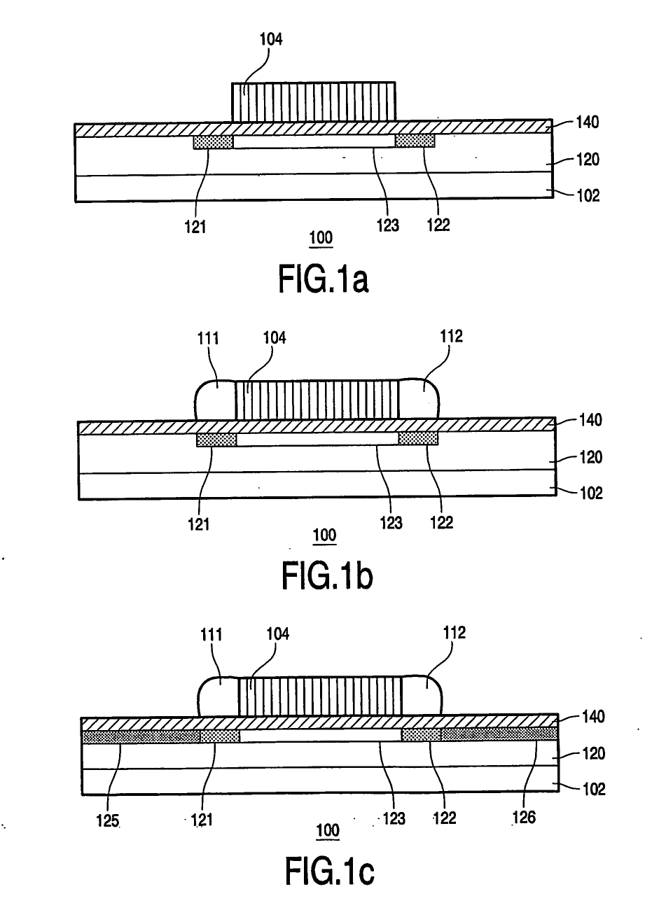

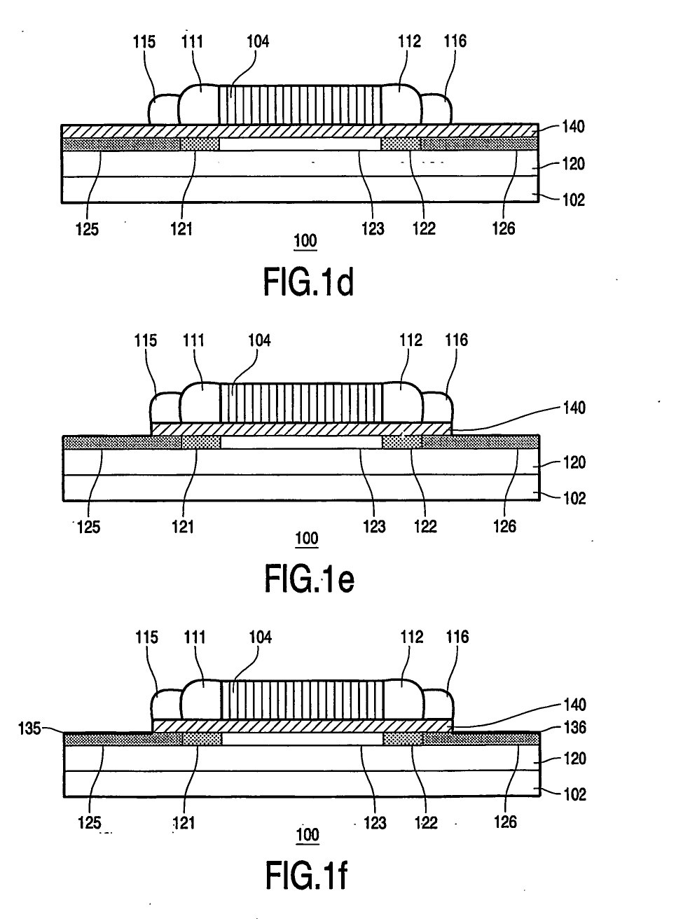

FIGS. 1a-1f schematically show the various steps leading to a TFT according to the present invention; and

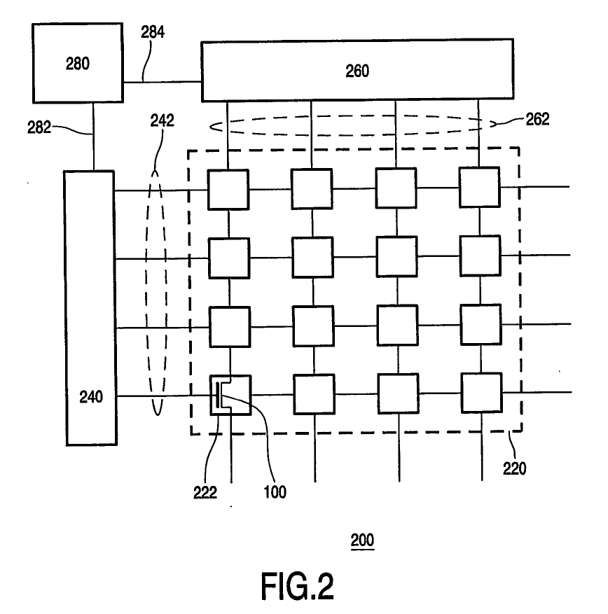

FIG. 2 schematically depicts an electronic device according to the present invention.

FIG. 1a schematically depicts a first intermediate structure of a TFT 100. The TFT 100 is mounted on a substrate 102, which is covered by a semiconductor layer 120. The semiconductor layer 120 may be formed by known techniques, and may for instance comprise microcrystalline silicon, a polycrystalline silicon (polysilicon) or a crystalline silicon material. It is emphasized that the polysilicon material may be formed from a deposition of an amorphous silicon layer followed by a crystallisation step. The crystallisation step may be done by known techniques, such as laser-induced crystallisation or temperature controlled crystallisation.

An oxide layer 140, which again may have been formed using known deposition techniques, covers the semiconductor layer 120. On top of the oxide layer 140 a conductive gate 104 is mounted. The conductive gate 104 may have been formed by the deposition of a metal, such as aluminium for example, on the oxide layer 140 and the subsequent step of patterning of the metal to shape the conductive gate 104. Subsequently, the conductive gate 104 has been used as a mask in a self-aligned implantation step where a first doped region 121 and a second doped region 122 are implanted in the semiconductor layer 120, leaving the conductive gate 104 covering an undoped region 123 in between the first doped region 121 and the second doped region 122. The first doped region 121 and second doped region 122 have been formed using a low-dose implant to introduce field relief in these regions.

FIG. 1b shows a second intermediate structure of TFT 100 that is obtained after providing a first spacer 111 and a second spacer 112 adjacent to the first side and second side of the conductive gate 104 respectively. The first spacer 111 is placed adjacent to and in contact with a first side of the conductive gate 104 that is oriented substantially perpendicular to the oxide layer 140, and the second spacer 112 is placed adjacent to and in contact with a second side of the conductive gate 104, the second side also being oriented substantially perpendicular to the oxide layer 140. Preferably, the first spacer 111 and the second spacer 112 are formed by depositing a layer of spacer material over the exposed surface of the second intermediate structure and patterning this spacer material to form the first spacer 111 and the second spacer 112, for instance by means of an anisotropic etching step. However, other formation techniques, like selective deposition are also feasible.

The first spacer 111 and the second spacer 112 at least partially cover the first doped region 121 and the second doped region 122 respectively, and may primarily serve, in combination with the conductive gate 104, as a further mask for a subsequent step in of the method of the present invention, in which case the first spacer 111 and the second spacer 112 may be insulating spacers, which may be formed from amorphous silicon. Alternatively, if the first spacer 111 and the second spacer 112 should also have the function of providing enhanced control over the occurrence of detrimental hot carrier effects, or the function of improving the conductivity in the channel to be formed under the conducting gate 104 between the first doped region 121 and the second doped region 122, the first spacer 111 and the second spacer 112 can be formed from a conductive spacer material. The first spacer 111 and the second spacer 112 may also be formed by a conductive part in contact with the conductive gate 104 and by a non-conductive part.

FIG. 1c shows a third intermediate structure of the TFT 100 that is obtained after performing a second step of the present method, that is, implanting a first further doped region 125 and a second further doped region 126 into the semiconductor layer 120 using the conductive gate 104, the first spacer 111 and the second spacer 112 as a further mask, the first further doped region 125 and the second further doped region 126 being more conductive than the first doped region 121 and the second doped region 122. Typically, the first further doped region 125 and the second further doped region 126 define the source and drain areas of the TFT 100. At this point, it is emphasized that the step of implanting the first doped region 121 and the second doped region 122 as described in the detailed description of FIG. 1A may comprise the implantation of a low-dose dopant in an area of the semiconductor layer 120 that include the areas covered by the first doped region 121 and the first further doped region 125 and the second doped region 122 and the second further doped region 126 respectively. In that case, the step of implanting the first further doped region 125 and the second doped region 126 merely comprises increasing the low-dope concentration in these areas to a higher-dope concentration.

FIG. 1d shows a fourth intermediate structure of the TFT 100 that is obtained after performing a third step of the present method, that is, providing a first insulating spacer 115 adjacent to the first spacer 111 opposite the first side of the conductive gate 104 and a second insulating spacer 116 adjacent to the second spacer 112 opposite the second side of the conductive gate 104. The first insulating spacer 115 and the second insulating spacer 116 are formed on top of the oxide layer 140, which has the advantage that a leakage path from the conductive gate 104 to either the first further doped region 125 or to the second further doped region 126 extends over the oxide layer 140 under the first spacer 111 and the first insulating spacer 115 or under the second spacer 112 and the second insulating spacer 116. Since the oxide layer 140 ideally is free of pinholes, this arrangement leads to longer, less conductive parasitic paths for the TFT 100.

The first insulation spacer 115 and the second insulation spacer 116 preferably are formed by depositing a layer of insulating material on the exposed surface of the third intermediate structure of the TFT 100 and patterning the insulating material to form the first insulation spacer 115 and the second insulation spacer 116, for instance by means of etching techniques. However, other ways of providing the first insulation spacer 115 and the second insulation spacer 116 are also feasible, like selective deposition.

It is emphasized that, even if the first spacer 111 and the second spacer 112 are insulating spacers, the presence of the first insulation spacer 115 and the second insulation spacer 116 may be advantageous, for instance because the lateral dimensions of the first spacer 111 and the second spacer 112 are chosen for the purposes of the self-aligned implantation of the first further doped region 125 and the second further doped region 126, in which case these dimensions may not suffice to provide for an appropriate insulation between the conductive gate 104 and the electrodes connected to the source and drain of the TFT 100.

FIG. 1e shows a fifth intermediate structure of the TFT 100 that is obtained after performing a fourth step of the method on the fourth intermediate structure of the TFT 100, that is removing an exposed area of the oxide layer 140 covering the first further doped region 125 and the second further doped region 126. This step may be realized by known etching techniques and by using the conductive gate 104, the first spacer 111, the second spacer 112, the first insulating spacer 115 and the second insulating spacer 116 as a mask in a self-aligned process. This step is performed to enable the connection of the first further doped region 125 and the second further doped region 126, that is the source and drain region of the TFT 100, with a conductive contact.

FIG. 1f schematically shows the TFT 100 that is obtained after a fifth step of the method, that is, providing the first further doped region 125 with a first conductive contact 135 and a the second further doped region 126 with second conductive contact 136. This may be realized by a self-aligned process, in which a metal is deposited on the exposed areas of the semiconductor layer 120 over the first further doped region 125 and the second further doped region 126. The metal is subsequently reacted with the semiconductor layer 120 to form the first conductive contact 135 and the second conductive contact 136, with the conductive material being silicide. Subsequently, unreacted material is removed from the exposed surface of the TFT 100. Because the semiconductor layer 120 has been protected by the oxide layer 140 during the processing steps of the TFT 100, no significant contamination will have built up over the first further doped region 125 and the second further doped region 126. Therefore, the formation of the silicide contacts 135 and 136 will not be influenced by the presence of significant contaminant concentrations, thus yielding high quality silicide contacts.

At this point it is emphasized that it is not necessary for TFT 100 as shown in FIG. 1 to be formed by the method described in FIG. 1 and its detailed description; the teachings of the present invention should protect the structure of the TFT 100 as shown in FIG. 1F regardless of the way the TFT 100 is made.

FIG. 2 shows a schematic example of a relevant part of an electronic device 200 that typically benefits from the teachings of the present invention. Electronic device 200 has an active matrix (AM) array 220 coupled to a first driver circuit arrangement 240 via a plurality of conductors 242. In addition, the active matrix array 220 is coupled to a second driver circuit arrangement 260 via a further plurality of conductors 262. The first driver circuit arrangement 240, the second driver circuit arrangement 260, the plurality of conductors 242 and the further plurality of conductors 262 may form an integral part of the active matrix array 220. The first driver circuit arrangement 240 and the second driver circuit arrangement 260 are coupled to a power supply 280 via respective power lines 282 and 284, and are arranged to selectively drive a matrix element 222 to a predefined state. Matrix element 222 may comprise a pixel of an AMLCD. Each matrix element 222 includes a TFT 100, although it is only shown in the bottom left matrix element 222 for reasons of clarity only.

The conductivity of the parasitic paths between the conductive gate 104 and the source/drain regions, that is, the first further doped region 125 and the second further doped region 126 of the TFT 100 have a distinct impact both the performance of the matrix array 220 as well as on the power consumption of the electronic device 200. The higher this conductivity becomes, the more difficult it becomes to maintain the output quality of the active matrix array 220, and the higher the power consumption of the electronic device 200 becomes. The latter is particularly problematic for battery-powered devices where the power supply 280 comprises a set of batteries or a battery pack, because this reduces the operational time of the electronic device 200. This is an important disadvantage, because the operational time of the electronic device 200, that is, the time that the electronic device 200 can operate before the batteries have to be replaced or recharged, is an important marketing parameter.

Therefore, it is an important advantage if the TFT 100 in a matrix element 220 is a TFT according to the teachings of the present invention and for example as shown in FIG. 1 and its detailed description, because the introduction of such a TFT 100 improves the lifetime of other elements of the electronic device 200, that is the power supply 280, especially if the power supply 280 comprises battery means. This advantage becomes even more pronounced if the first driver circuit arrangement 240 and the second driver circuit arrangement 260 are also formed using a TFT 100 according to the teachings of the present invention, since this further adds to the reduction of parasitic currents in the electronic device 200.

In addition, the reduction of the conductivity of the parasitic path between the conducting gate 104 and at least one of the first further doped region 125 and the second further doped region 126 of the TFT 100 as shown in FIG. 1 and described in the accompanying detailed description has the advantage that the yield of the components that include the TFTs 100, like the active matrix array 220, the first driver circuit arrangement 240 or the second driver circuit arrangement 260, is improved. Consequently, the electronic device 200 can be marketed at a more competitive price.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. The word “comprising” does not exclude the presence of elements or steps other than those listed in a claim. The word “a” or “an” preceding an element does not exclude the presence of a plurality of such elements. The invention can be implemented by means of hardware comprising several distinct elements. In the device claim enumerating several means, several of these means can be embodied by one and the same item of hardware. The mere fact that certain measures are recited in mutually different dependent claims does not indicate that a combination of these measures cannot be used to an advantage.

1. A thin film transistor on a substrate comprising:
a semiconductor layer having a first doped region and a second doped region in between a first further doped region and a second further doped region, and having an undoped region in between the first doped region and the second doped region, the first doped region and the second doped region having a lower conductivity than the first further doped region and the second further doped region; and
an oxide layer partially covering a surface of the semiconductor layer, the oxide layer carrying:
a conductive gate over the undoped region having a first side and a second side substantially perpendicular to the oxide layer;
a first spacer and a second spacer adjacent to the first side and second side of the conductive gate respectively;
a first insulating spacer adjacent to a side of the first spacer opposite the first side of the conductive gate; and
a second insulating spacer adjacent to a side of the second spacer opposite the second side of the conductive gate;
the thin film transistor further comprising:
a first conductive contact with the first further doped region; and
a second conductive contact with the second further doped region.

2. A thin film transistor as claimed in claim 1, wherein the first spacer and the second spacer comprise a conductive material.

3. A thin film transistor as claimed in claim 1, wherein the first conductive contact and the second conductive contact comprise a silicide layer.

4. A thin film transistor as claimed in claim 1, wherein the semiconductor layer comprises a polycrystalline silicon material.

5. A method for producing a thin film transistor on a substrate comprising a semiconductor layer having an undoped region in between a first doped region and a second doped region and an oxide layer partially covering a surface of the semiconductor layer, the oxide layer carrying a conductive gate over the undoped region, the conductive gate having a first side and a second side substantially perpendicular to the oxide layer; the first doped region and the second doped region having been formed in a self-alignment step using the conductive gate as a mask, the method comprising the steps of:
providing a first spacer and a second spacer on the oxide layer adjacent to the first side and second side of the conductive gate respectively;
implanting a first further doped region and a second further doped region into the semiconductor layer using the conductive gate, the first spacer and the second spacer as a further mask, the first further doped region and the second further doped region being more conductive than the first doped region and the second doped region;
providing a first insulating spacer on the oxide layer adjacent to the first spacer opposite the first side of the conductive gate and a second insulating spacer on the oxide layer adjacent to the second spacer opposite the second side of the conductive gate;
removing an exposed area of the oxide layer covering the first further doped region and the second further doped region; and
providing the first further doped region with a first conductive contact and the second further doped region with a second conductive contact.

6. A method as claimed in claim 5, wherein the step of providing a first spacer and a second spacer comprises depositing a conductive spacer material.

7. A method as claimed in claim 5, wherein the step of providing the first further doped region with a first conductive contact and the second further doped region with a second conductive contact comprises reacting a conductive material with the semiconductor layer to form a silicide.

8. A method as claimed in claim 5, wherein the step of removing an exposed area of the oxide layer covering the first further doped region and the second further doped region is performed using the conductive gate, the first spacer, the second spacer, the first insulating spacer and the second insulating spacer as a mask.

9. An electronic device comprising an active matrix array coupled to a first driver circuit arrangement and a second driver circuit arrangement, the first driver circuit arrangement and the second driver circuit arrangement being coupled to a power supply, at least one of the matrix array, the first driver circuit arrangement and the second driver circuit arrangement comprising a plurality of thin film transistors as claimed in any of the claims 1-4.

10. An electronic device as claimed in claim 9, wherein the power supply comprises battery means.

11. A thin film transistor substantially as described herein with reference to the drawings.

12. A method for producing a thin film transistor substantially as described herein with reference to the drawings.

13. An electronic device substantially as described herein with reference to the drawings.
